(19) United States
(12) Patent Application Publication
(10) Pub. No.: US 2014/0353762 A1
(43) Pub. Date: Dec. 4, 2014

(54) MULTI-ORIENTATION SEMICONDUCTOR DEVICES EMPLOYING DIRECTED SELF-ASSEMBLY

(71) Applicant: International Business Machines Corporation, Armonk, NY (US)

(72) Inventors: Michael A. Guillorn, Yorktown Heights, NY (US); Isaac Lauer, Yorktown Heights, NY (US); Jeffrey W. Sleight, Ridgefield, CT (US); HsinYu Tsai, White Plains, NY (US)

(73) Assignee: International Business Machines Corporation, Armonk, NY (US)

(21) Appl. No.: 14/021,290

(22) Filed: Sep. 9, 2013

Related U.S. Application Data
(63) Continuation of application No. 13/903,118, filed on May 28, 2013.

(51) Int. Cl. H01L 27/088

(52) U.S. Cl. CPC H01L 27/0886
USPC 257/390

(57) ABSTRACT

A template material layer is deposited over a substrate, and is patterned with at least two trenches having different lengthwise directions. An array of polymer lines are formed by directed self-assembly of a copolymer material and a selective removal of one type of polymer material relative to another type within each trench such that the lengthwise direction of the polymer lines are parallel to the lengthwise sidewalls of the trench. The patterns in the arrays of polymer lines are transferred into an underlying material layer to form arrays of patterned material structures. The arrays of patterned material structures may be arrays of semiconductor material portion, or may be arrays of gate electrodes. An array of patterned material structures may be at a non-orthogonal angle with respect to an array of underlying material portions or with respect to an array of overlying material portions to be subsequently formed.

### CROSS REFERENCE TO RELATED APPLICATION

This application is a continuation of U.S. patent application Ser. No. 13/903,118, filed May 28, 2013 the entire content and disclosure of which is incorporated herein by reference.

### BACKGROUND

The present disclosure relates generally to a method for forming semiconductor devices including multiple device orientations, and particularly to a method for forming semiconductor devices employing directed self-assembly of block copolymers, and structures formed by the same.

Lithographic limitations limit the direction along which features having lithographic minimum dimensions can be printed. For example, features having a minimum lithographically printable pitch can be printed only along a predetermined direction in advanced semiconductor devices. The limitations on the orientation of structures having lithographic minimum dimensions prevent formation of surfaces at arbitrary angle relative to a permissible surface orientation for semiconductor devices.

### SUMMARY

A template material layer is deposited over a substrate, and is patterned with at least two trenches having different lengthwise directions. An array of polymer lines are formed by directed self-assembly of a copolymer material and a selective removal of one type of polymer material relative to another type within each trench such that the lengthwise direction of the polymer lines are parallel to the lengthwise sidewalls of the trench. The patterns in the arrays of polymer lines are transferred into an underlying material layer to form arrays of patterned material structures. The arrays of patterned material structures may be arrays of semiconductor material portions such as semiconductor fins, or may be arrays of gate electrodes. An array of patterned material structures may be at a non-orthogonal angle with respect to an array of underlying material portions or with respect to an array of overlying material portions to be subsequently formed.

According to an aspect of the present disclosure, a method of forming a patterned structure is provided. A material layer including a first material is formed over a substrate. First lamellae of a polymer material are formed in a first region and second lamellae of the polymer material are formed in a second region. The first lamellae extend along a first direction and the second lamellae extend along a second direction that is not parallel to, and is not perpendicular to, the first direction, and the first lamellae and the second lamellae have a same uniform width throughout. A first array of line structures is formed in the first region and a second array of line structures is formed in the second region over the substrate by transferring a pattern of the first lamellae and by transferring a pattern of the second lamellae, respectively, into the material layer. Prior to, or after, forming the first and second arrays of line structures, a third array of line structures is formed in the first region and a fourth array of line structure in the second region. The third array of line structures and the fourth array of line structures include a second material. Each line structure within the third and fourth arrays of line structures extends along a third direction that is different from the first direction and the second direction.

According to another aspect of the present disclosure, a structure is provided, which includes a first array of line structures in a first region and a second array of line structures in a second region, and a third array of line structures in the first region and a fourth array of line structure in the second region. The first array of line structures and the second array of line structures include a first material. The third array of line structures and the fourth array of line structures include a second material different from the first material and overlie, or underlie, the first array of line structures and the second array of line structures, respectively. Each line structure in the first array of line structures extends along a first direction and each line structure in the second array of line structures extends along a second direction that is not parallel to, and is not perpendicular to, the first direction. The first array of line structures and the second array of line structures have a same uniform width throughout. The same uniform width can be in a range from 2 nm to 80 nm. Each line structure within the third and fourth arrays of line structures extends along a third direction that is different from the first direction and the second direction.

### BRIEF DESCRIPTION OF SEVERAL VIEWS OF THE DRAWINGS

FIG. 1A is a top-down view of a first exemplary structure including a first material layer over a substrate after formation of a patterned template layer according to a first embodiment of the present disclosure.

FIG. 1B is a vertical cross-sectional view of the first exemplary patterned structure along the vertical plane B-B′ of FIG. 1A.

FIG. 2A is a top-down view of the first exemplary patterned structure formation of lamellae within trenches in the patterned template layer according to the first embodiment of the present disclosure.

FIG. 2B is a vertical cross-sectional view of the first exemplary patterned structure along the vertical plane B-B′ of FIG. 2A.

FIG. 3A is a top-down view of the first exemplary patterned structure after transfer of the pattern of the lamellae into the first material layer according to the first embodiment of the present disclosure.

FIG. 3B is a vertical cross-sectional view of the first exemplary patterned structure along the vertical plane B-B′ of FIG. 3A.

FIG. 4A is a top-down view of the exemplary patterned structure after deposition and patterning of a second material layer according to the first embodiment of the present disclosure.

FIG. 4B is a vertical cross-sectional view of the exemplary patterned structure along the vertical plane B-B′ of FIG. 4A.

FIG. 5A is a magnified view of the first exemplary patterned structure of FIG. 4A.

FIG. 5B is a vertical cross-sectional view of the magnified view of the first exemplary patterned structure along the vertical plane B-B′ of FIG. 5A.

FIG. 6A is a top-down view of the first exemplary patterned structure after formation of metal interconnect structures according to the first embodiment of the present disclosure.

FIG. 6B is a vertical cross-sectional view of the first exemplary patterned structure along the vertical plane B-B′ of FIG. 6A.

FIG. 7A is a top-down view of a second exemplary patterned structure after patterning a second material layer according to a second embodiment of the present disclosure.

FIG. 7B is a vertical cross-sectional view of the second exemplary patterned structure along the vertical plane B-B′ of FIG. 7A.

FIG. 8A is a top-down view of the second exemplary patterned structure deposition of a first material layer and a template layer, patterning of the template layer with trenches, and formation of lamellae within the trenches in the template layer according to the second embodiment of the present disclosure.

FIG. 8B is a vertical cross-sectional view of the second exemplary patterned structure along the vertical plane B-B′ of FIG. 8A.

FIG. 9A is a top-down view of the second exemplary patterned structure after patterning the first material layer according to the second embodiment of the present disclosure.

FIG. 9B is a vertical cross-sectional view of the second exemplary patterned structure along the vertical plane B-B′ of FIG. 9A.

FIG. 10A is a top-down view of the second exemplary patterned structure after selective removal of the lamellae according to the second embodiment of the present disclosure.

FIG. 10B is a vertical cross-sectional view of the second exemplary patterned structure along the vertical plane B-B′ of FIG. 10A.

FIG. 11A is a top-down view of a third exemplary patterned structure after filling cavities between lamellae with fill material portions according to a third embodiment of the present disclosure.

FIG. 11B is a vertical cross-sectional view of the third exemplary patterned structure along the vertical plane B-B′ of FIG. 11A.

FIG. 12A is a top-down view of the third exemplary patterned structure after removal of the lamellae and after patterning of an underlying material layer employing the fill material portions as an etch mask according to the third embodiment of the present disclosure.

FIG. 12B is a vertical cross-sectional view of the third exemplary patterned structure along the vertical plane B-B′ of FIG. 12A.

### DETAILED DESCRIPTION

As stated above, the present disclosure relates to a method for forming semiconductor devices employing directed self-assembly of block copolymers, and structures formed by the same. Aspects of the method are now described in detail with accompanying figures. It is noted that like and corresponding elements are referred to by like reference numerals. As used herein, ordinals such as “first,” “second,” and “third,” etc. are employed to distinguish similar elements, and a same element may be labeled with different ordinals across the specification and the claims.

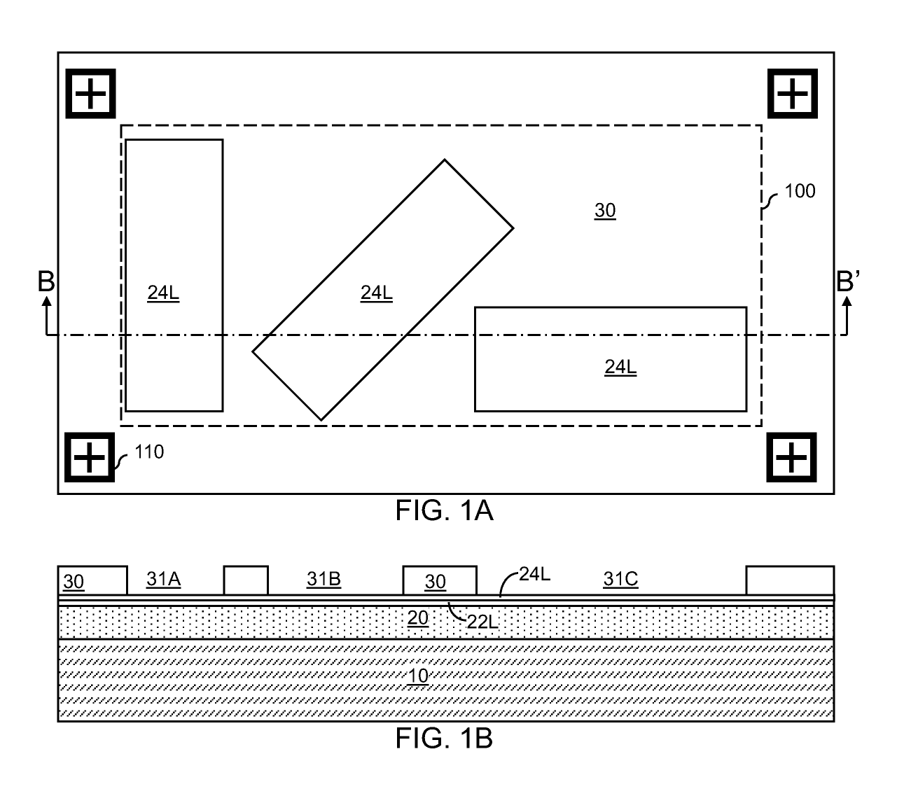

Referring to FIGS. 1A and 1B, a first exemplary structure according to a first embodiment of the present disclosure includes a substrate 10. The substrate 10 can be include a semiconductor substrate such as a single crystalline semiconductor substrate of a semiconductor material such as silicon, an alloy of at least two elemental semiconductor elements, or a compound semiconductor material. The substrate 10 may include semiconductor devices such as deep trench capacitors, resistors, diodes, or other semiconductor devices. Alternatively or additionally, the substrate 10 can include a dielectric material such as silicon oxide, silicon nitride, or silicon oxynitride. In one embodiment, the substrate 10 can include a stack of a handle substrate (not shown separately) and an insulator layer (not shown separately) such that the insulator is located over the handle substrate. In one embodiment, the insulator layer can be a buried insulator layer of a semiconductor-on-insulator substrate (SOI) substrate as known in the art.

A first material layer 20 is provided, or formed, on the substrate 10. The first material layer can be a semiconductor material layer, an insulator layer, or a conductive material layer. In one embodiment, the first material layer 20 can be a single crystalline semiconductor material layer including a semiconductor material such as silicon, an alloy of at least two elemental semiconductor elements, or a compound semiconductor material. In one embodiment, the first material layer 20 can be a top semiconductor layer of an SOI substrate.

A hard mask layer 22L including a dielectric material can be optionally formed on the top surface of the first material layer 20. The dielectric material of the hard mask layer 22L can be, for example, silicon oxide, silicon nitride, and/or a polymer material layer. The hard mask layer 22L can provide the function of increasing etch budget in case block copolymer material portions do not provide sufficient etch selectivity with respect to the material of the first material layer 20.

A neutral material layer 24L can be optionally formed on the top surface of the hard mask layer 22L, if the hard mask layer 22L is present, or on the top surface of the first material layer 20. The neutral material layer 224L includes a material that causes bottom surfaces of block copolymer material portions to align vertically with respect to the substrate 10. If a hard mask layer 22L is provided, the neutral material layer 24L can be a thin polymer material layer having a thickness in a range from 3 nm to 30 nm. If the neutral material layer 24L is formed directly on the top surface of the first material layer 20, the neutral material layer 24L can have a thickness in a range from 10 nm to 100 nm, and can include a material such as silicon oxide and/or silicon nitride.

Alignment mark structures 110 can be formed in the first material layer 20 and/or the substrate 10 and/or the hard mask layer 22L and/or the neutral material layer 24L employing methods known in the art. The alignment mark structures 110 can be employed to provide alignment between preexisting structures and a new pattern to be formed in a photoresist layer in a lithographic exposure step. The alignment mark structures 110 can be formed, for example, in kerf regions that surround a semiconductor chip region 100. The semiconductor chip region 100 corresponds to the area of the first material layer 20 and the substrate 10 that is subsequently diced to form a semiconductor chip. In one embodiment, a periphery of the semiconductor chip region 100, which defines the lateral extent of the semiconductor chip to be subsequently diced, can include a first pair of parallel edges (e.g., edges perpendicular to the vertical plane B-B′) and a second pair of parallel edges (e.g., edges parallel to the vertical plane B-B′). In one embodiment, the first pair of parallel edges can be perpendicular to the second pair of parallel edges. A Cartesian coordinate system can be oriented such that the first pair of parallel edges is parallel to the y-axis, and the second pair of parallel edges is parallel to the x-axis.

Patterned guiding structures for inducing self-assembly of a block copolymer material are subsequently formed over the top surface of the first material layer 20. The block copolymer material refers to a polymer material including a plurality of blocks of polymerized monomer units such that each block includes a same type of polymerized monomers. The patterned guiding structures may be a template layer 30 including trenches therein such that sidewalls of the trenches guide a subsequent self-assembly of a block copolymer material, or may be thin patterned layers having edges that guide a subsequent self-assembly of a block copolymer material, or any other temporary structure that may be employed to guide a subsequent self-assembly of a block copolymer material.

The directions of the patterned guiding structures are selected to be different across different regions. Selection of the different directions for the patterned guiding structures is illustrated employing three different device regions, which are herein referred to as a first region, a second region, and a third region, although formation of the third region is optional and formation of additional regions is also optional. A first guiding structure having edges extending along a first direction (which is a horizontal direction) can be formed in the first region, a second guiding structure having edges extending along a second direction (which is another horizontal direction) can be formed in a second region, and a third guiding structure having edges extending along a third direction (which is yet another horizontal direction) can be formed in the third region.

In an illustrative embodiment, the first guiding structure can be lengthwise sidewalls of a first rectangular trench 31A in which the lengthwise sidewalls extend along a y-axis in a Cartesian coordinate system, the second guiding structure can be lengthwise sidewalls of a second rectangular trench 31B in which the lengthwise sidewalls extend along a horizontal direction that is not parallel to the x-axis or to the y-axis, and the third guiding structure can be lengthwise sidewalls of a third rectangular trench 31C in which the lengthwise sidewalls extend along an x-axis in the Cartesian coordinate system. As used herein, a “lengthwise” direction or a “lengthwise” edge of a structure refers to a horizontal direction or an edge that extends along a longest pair of straight lines that are present in the structure. The ratio of the dimensions of the lengthwise edges and widthwise edges of the rectangular trenches (31A, 31B, 31C) can be selected to be conducive to directed self-assembly of a block copolymer material to be subsequently applied therein. As used herein, a “widthwise” direction or a “widthwise” edge of a structure refers to a horizontal direction that is perpendicular to the lengthwise direction of the structure.

If the patterned guiding structures are sidewalls of the trenches (31A, 31B, 31C) in a template layer 30, the first trench 31A can be formed in the first region, the second trench can be formed in the second region, and the third trench 31C can be optionally formed in the third region. A first parallel pair of lengthwise sidewalls of the first trench 31A extending along the y-axis can be the first guiding structure, a second parallel pair of lengthwise sidewalls of the second trench 31B can be the second guiding structure, and a third parallel pair of lengthwise sidewalls of the third trench 31C can be the third guiding structure.

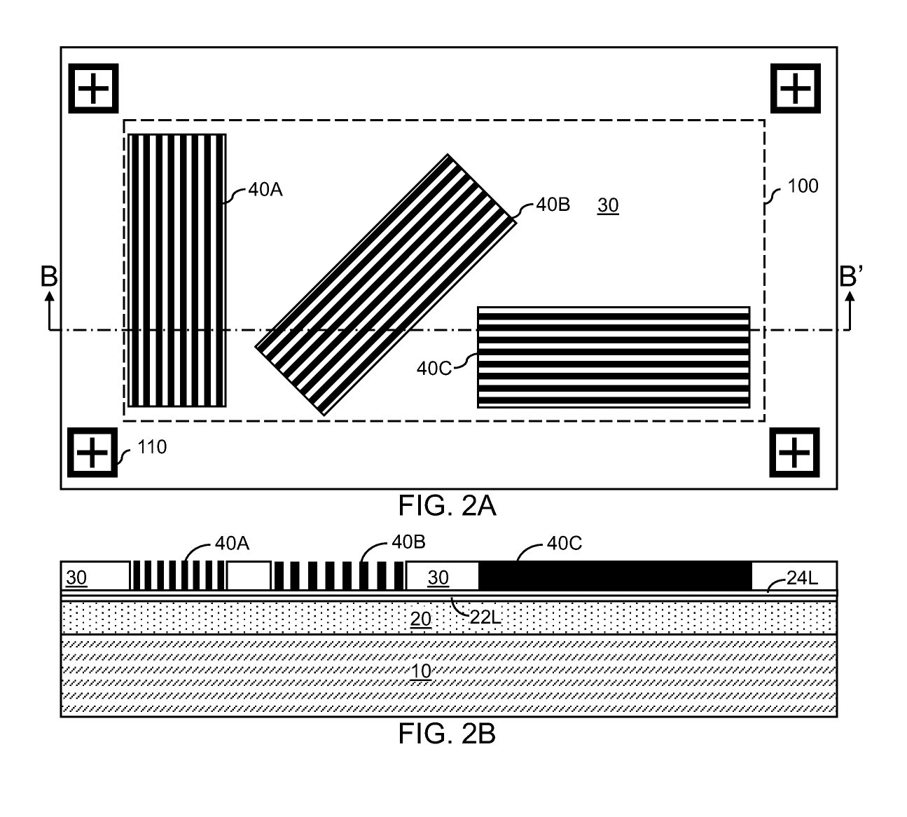

Referring to FIGS. 2A and 2B, a block copolymer material is applied over the first material layer 20, for example, by spin coating. The block copolymer material includes a polymer material (which is herein referred to as a first polymer material) and a second polymer material over the first material layer 20. If the patterned guiding structures are sidewalls of the trenches (31A, 31B, 31C) in a template layer 30, the block copolymer material can be applied within the trenches (31A, 31B, 31C). The patterned guiding structures are material portions that induce self-alignment of a block copolymer material. Non-limiting examples of the patterned guiding structures include hydrogen silsesquioxane (HSQ), methyl silsesquioxane (MSQ), a photoresist material, and carbon-based hard mask materials such as organo-silicate glass (OSG). The block copolymer material can be applied over such patterned guiding structures.

The block copolymer material includes a first polymeric block component and a second polymeric block component that are immiscible with each other. The block copolymer material may be self-planarizing. The block copolymer material includes self-assembling block copolymers that are capable of self-organizing into nanometer-scale patterns. A molecule of the block copolymer material can include polymerized monomer units of a first polymer material, i.e., a first polymeric block component, and polymerized monomer units of a second polymer material, i.e., a second polymeric block component. The first polymeric block component and the second polymeric block component are selected such that a self-aligned assembly of first polymer blocks including the first polymeric block component and second polymer blocks including the second polymeric block component can be subsequently formed upon phase separation of the first and second polymeric block components.

Exemplary materials for the first polymeric block component and the second polymeric block component are described in U.S. Pat. No. 7,605,081 to Yang et al., issued on Oct. 20, 2009, the contents of which are incorporated herein by reference. Specific examples of self-assembling block copolymers may include, but are not limited to: polystyrene-block-polymethylmethacrylate (PS-b-PMMA), polystyrene-block-polyisoprene (PS-b-PI), polystyrene-block-polybutadiene (PS-b-PBD), polystyrene-block-polyvinylpyridine (PS-b-PVP), polystyrene-block-polyethyleneoxide (PS-b-PEO), polystyrene-block-polyethylene (PS-b-PE), polystyrene-b-polyorganosilicate (PS-b-POS), polystyrene-block-polyferrocenyldimethylsilane (PS-b-PFS), polyethyleneoxide-block-polyisoprene (PEO-b-PI), polyethyleneoxide-block-polybutadiene (PEO-b-PBD), polyethyleneoxide-block-polymethylmethacrylate (PEO-b-PMMA), polyethyleneoxide-block-polyethylethylene (PEO-b-PEE), polybutadiene-block-polyvinylpyridine (PBD-b-PVP), and polyisoprene-block-polymethylmethacrylate (PI-b-PMMA).

The self-assembling block copolymers are first dissolved in a suitable solvent system to form a block copolymer solution, and the block copolymer solution is applied over the first material layer 20 (for example, into the trenches (31A, 31B, 31C). The solvent system used for dissolving the block copolymer and forming the block copolymer solution may include any suitable solvent, which can include, but is not limited to: toluene, propylene glycol monomethyl ether acetate (PGMEA), propylene glycol monomethyl ether (PGME), and acetone. The block copolymer material is not a conventional photoresist that may be developed upon exposure to ultraviolet light or optical light. Also, the block copolymer material is not a conventional low-k dielectric material.

Directed self-assembly of the block copolymer material is induced. The guiding structures (such as lengthwise sidewalls of the trenches (31A, 31B, 31C) in the template layer 20) guide phase separation and alignment of the block copolymer material during the directed self-assembly. Components of the block copolymer material are aligned to the various guiding structures during the directed self-assembly. In one embodiment, the block copolymer material is annealed by thermal annealing at an elevated temperature to form the lamellae (40A, 40B, 40C) including the first polymeric block component and complementary lamellae (not shown) including the second polymeric block component. The anneal may be performed, for example, at a temperature from about 200° C. to about 300° C. for a duration from about 2 minutes to about 10 hours. Alternatively, solvent annealing may be employed in lieu of thermal annealing or in conjunction with thermal annealing.

The phase separation and alignment of the block copolymer material forms a nanoscale self-assembled self-aligned structure that is self-aligned to the guiding structures. The nanoscale self-assembled self-aligned structure is herein referred to as a “self-aligned assembly.” First lamellae 40A including the first polymer material, i.e., the first polymeric block component, are formed within the first trench 31A (See FIG. 1A) in the first region, second lamellae 40B including the first polymer material are formed within the second trench 31B (See FIG. 1A) in the second region, and additional lamellae 40C including the first polymer material are formed within the additional trench 31C (See FIG. 1A) in the third region. Thus, the first lamellae 40A, the second lamellae 40B, and the additional lamellae 40C are portions of the block copolymer material that include the first polymer material. First complementary lamellae (not shown) including the second polymer material, i.e., the second polymeric block component, fills the spaces within the first trench 31A that are not filled by the first lamellae 40A. Second complementary lamellae (not shown) including the second polymer material fills the spaces within the second trench 31B that are not filled by the second lamellae 40B. Additional complementary lamellae (not shown) including the second polymer material fills the spaces within the third trench 31C that are not filled by the additional lamellae 40C.

The geometrical features of the guiding structures control the orientations of the various lamellae (40A, 40B, 40C) including the first polymeric material and the various lamellae including the second polymeric material. In general, the various lamellae (40A, 40B, 40C) including the first polymeric material and the various lamellae including the second polymeric material can extend along the lengthwise direction of the various local guiding structures (e.g., the lengthwise sidewalls of the various trenches (31A, 31B, 31C). The first lamellae 40A extend along a first direction (e.g., along the y-axis), the second lamellae extend along a second direction that is not parallel to, and is not perpendicular to, the first lengthwise direction, and the additional lamellae 40C extend along an additional direction (e.g., along the x-axis) that is perpendicular to the first direction.

At least a subset of the lamellae (40A, 40B, 40C) including the first polymer material and not contacting lengthwise sidewalls of the trenches (31A, 31B, 31C) can have a same width, which can be in a range from 2 nm to 80 nm. In this case, this width is the same as the length of the chain of the monomer units including the first polymeric material within a molecule of the block copolymer material. At least a subset of the complementary lamellae (not shown) including the second polymer material and not contacting lengthwise sidewalls of the trenches (31A, 31B, 31C) can have a same width, which can be in a range from 2 nm to 80 nm. The width of a complementary lamella may, or may not be, the same as the width of a lamella (40A, 40B, or 40C). In this case, this width is the same as the length of the chain of the monomer units including the second polymeric material within a molecule of the block copolymer material. Thus, when viewed excluding any outermost lamellae that may have a different width due to a physical contact with a lengthwise edge of a guiding structure, the first lamellae 40A, the second lamellae 40B, and the additional lamellae 40C can have a same uniform width throughout. Likewise, when viewed excluding any outermost complementary lamellae that may have a different width due to a physical contact with a lengthwise edge of a guiding structure, the complementary lamellae can have a same uniform width throughout.

The complementary lamellae can be subsequently removed selective to the first, second, and additional lamellae (40A, 40B, 40C), for example, by an anisotropic etch. In other words, portions of the second polymer material are removed selective to the first polymer material employing an etch chemistry that etches the second polymer material without substantially etching the first polymer material. The template layer 30 may, or may not, be removed during the anisotropic etch.

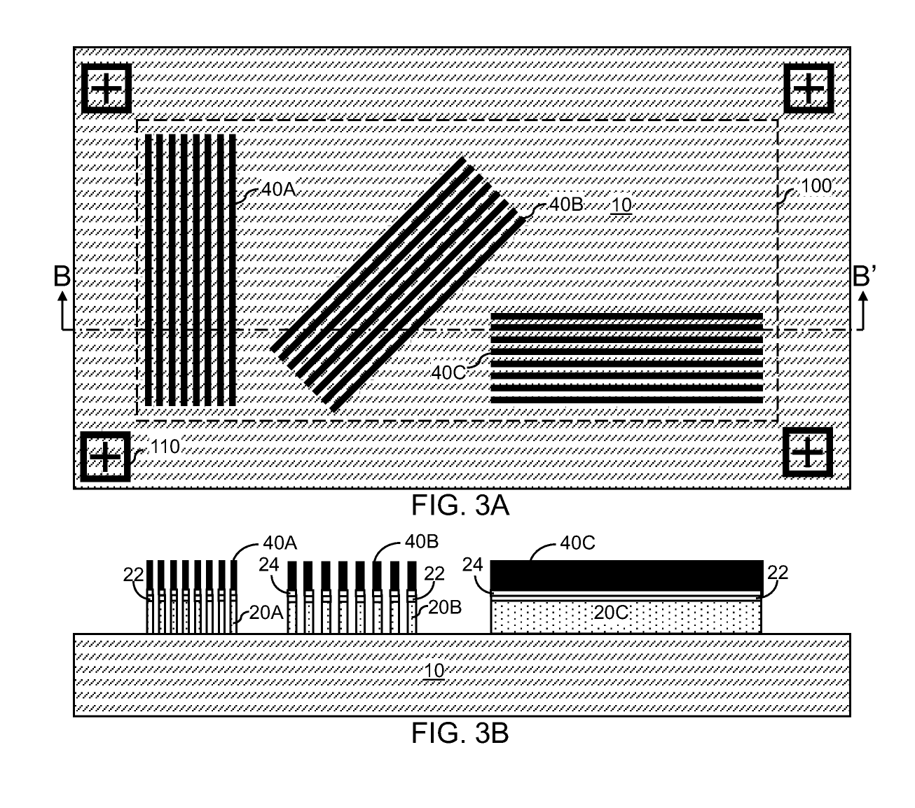

Referring to FIGS. 3A and 3B, a pattern based on the pattern of the lamellae (40A, 40B, 40C) is transferred into the first material layer 20. In one embodiment, the pattern of the lamellae (40A, 40B, 40C) can be transferred into the neutral material layer 24L (if present), the hard mask layer 22L (if present), and the first material layer 20 by anisotropically etching any remaining portion of the template layer 30, the neutral material layer 24L, the hard mask layer 22L, and the first material layer 20 employing the lamellae (40A, 40B, 40C) as an etch mask. Remaining portions of the neutral material layer 24L constitute neutral material portions 24. Remaining portions of the hard mask layer 22L constitute hard mask portions 22.

The remaining portions of the first material layer 20 after the anisotropic etch forms a first array 20A of line structures in the first region, a second array 20B of line structures in the second region, and an additional first-level array 20C of line structures in the third region. As used herein, a “line structure” refers to a structure having a uniform width defined by a pair of lengthwise sidewalls and having a same height throughout. As used herein, an “array” refers to a periodic repetition of structures such that a common feature, e.g., sidewalls, occurs at a same pitch. An array can be a periodic repetition of a unit structure at the same pitch. The transfer of the pattern of the first lamellae 40A forms the first array 20A of line structures, the transfer of the pattern of the second lamellae 40B forms the second array 20B of line structures, and the transfer of the pattern of the additional lamellae 40C forms the additional first-level array 20C of line structures.

In one embodiment, the material of the first material layer 20 can be a single crystalline semiconductor material. In this case, the first array 20A of line structures is a first array of semiconductor fins, the second array 20B of line structures is a second array of semiconductor fins, and the additional first-level array 20C of line structures is an additional first-level array of semiconductor fins.

The lamellae (40A, 40B, 40C) are subsequently removed, for example, by dissolving in a solvent. The neutral material portions 24 and the hard mask portions 22 can also be removed, for example, by a wet etch.

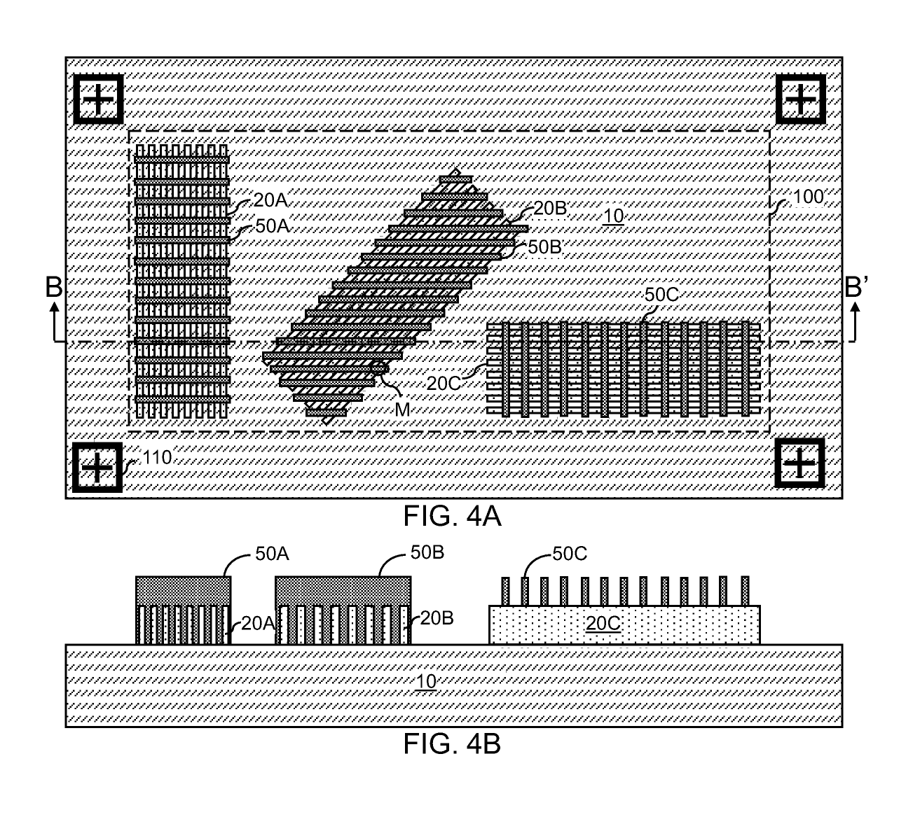

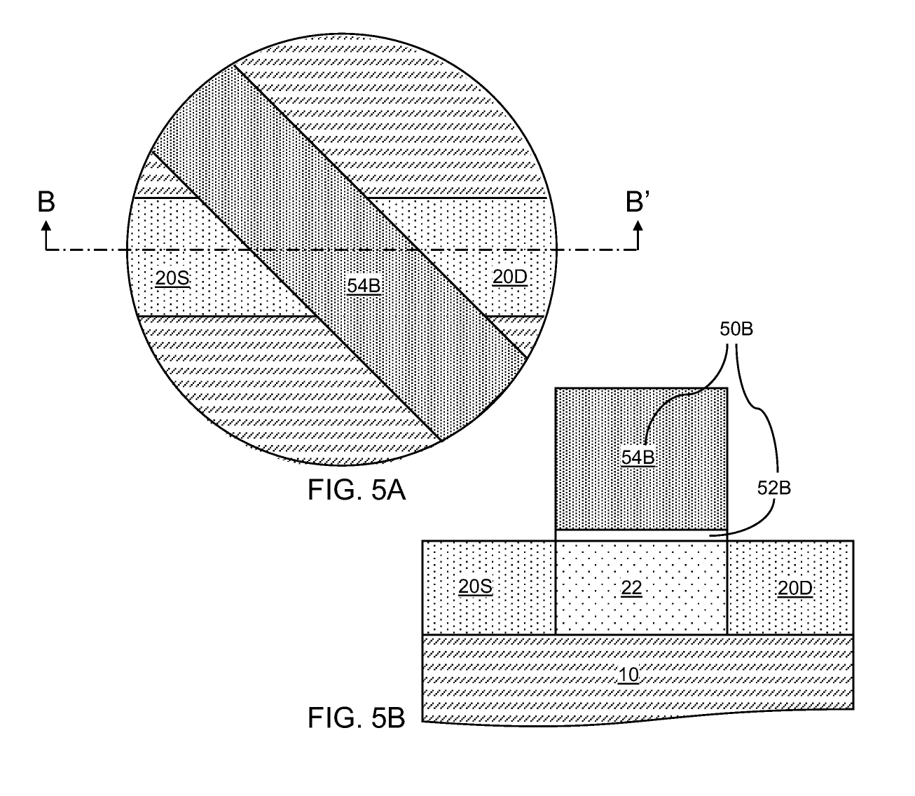

Referring to FIGS. 4A, 4B, 5A, and 5B, a second material layer including a second material is deposited and patterned. The second material layer can be a single layer or a stack of multiple layers. Correspondingly, the second material can be a single material or can be a combination of multiple materials corresponding to a stack of multiple layers. In an illustrative example, if the first, second, and additional first-level arrays (20A, 20B, 20C) of line structures are arrays of semiconductor fins, the second material layer can include a vertical stack, from bottom to top, of a gate dielectric layer, a gate conductor layer including a conductive material, and an optional gate cap dielectric layer. The second material layer can be deposited, for example, by chemical vapor deposition (CVD), physical vapor deposition (PVD), atomic layer deposition (ALD), or a combination thereof.

The second material layer is patterned to form a third array 50A of line structures in the first region, a fourth array 50B of line structures in the second region, and an additional second-level array 50C of line structures in the third region. The patterning of the second material layer can be performed, for example, by a combination of lithographic methods and an anisotropic etch, or by a combination of directed self-assembly method and an anisotropic etch in a manner similar to the processing steps of FIGS. 1A, 1B, 2A, 2B, 3A, and 3B. The anisotropic etch can be selective to the first material, i.e., the material of the first array 20A of line structures, the second array 20B of line structures, and the additional first-level array 20C of line structures.

In one embodiment, conventional lithographic methods can be employed to pattern the second material layer. In this case, the third array 50A of line structures and the fourth array 50B of line structures can extend along a same lengthwise direction, which is herein referred to as a third direction. In one embodiment, the third direction can be along the x-axis of the Cartesian coordinate. If the first-level additional array 20A of line structures is formed, the second-level additional array 50A of line structures may extend along a direction perpendicular to the third direction.

Thus, the third array 50A of line structures is formed in the first region and the fourth array 50B of line structure is formed in the second region. The third array 50A of line structures and the fourth array 50B of line structures include the second material. Each line structure within the third and fourth arrays (50A, 50B) of line structures extends along a third direction that is different from the first direction and the second direction. The third array 50A of line structures, the fourth array 50B of line structures, and the additional second-level array 50C of line structures are formed over the first array 20A of line structures, the second array 20B of line structures, and the additional first-level array 20C of line structures, respectively, and over the substrate 10.

In one embodiment, the first array 20A of line structures, the second array 20B of line structures, and the additional first-level array 20C of line structures can be arrays of semiconductor fins, and the third array 50A of line structures, the fourth array 50B of line structures, and the additional second-level array 50C of line structures can be arrays of gate electrode lines. For example, the third array 50A of line structures can be a first array of gate electrode lines, the fourth array 50B of line structures can be a second array of gate electrode lines, and the additional second-level array 50C of line structures can be a third array of gate electrode lines. Each gate line in the fourth array 50B of line structures can include a gate dielectric 50B and a gate electrode 54B. In this case, a source region, a drain region, and a body region can be formed in each of the underlying semiconductor fins. For example, a source region 20S and a drain region 20D can be formed around each gate electrode line and in each semiconductor fin, and a body region 22 can be formed underneath each gate electrode line and in each semiconductor fin.

In one embodiment, the first exemplary patterned structure can include a first array 20A of line structures in a first region and a second array 20B of line structures in a second region, and a third array 50A of line structures in the first region and a fourth array 50B of line structure in the second region. The first array 20A of line structures and the second array 20B of line structures include the first material, and the third array 50A of line structures and the fourth 50B array of line structures include the second material that is different from the first material. The third array 50A of line structures and the fourth 50B array of line structures overlie the first array 20A of line structures and the second array 20B of line structures, respectively. Each line structure in the first array 20A of line structures extends along a first direction, and each line structure in the second array 20B of line structures extends along a second direction that is not parallel to, and is not perpendicular to, the first direction. The first array 20A of line structures and the second array 20B of line structures can have a same uniform width throughout, which is the width of the first and second lamellae (40A, 40B; See FIG. 2A). The same uniform width can be in a range from 2 nm to 80 nm. Each line structure within the third and fourth arrays (50A, 50B) of line structures extends along a third direction that is different from the first direction and the second direction.

In general, first semiconductor devices can be formed in the first region on the substrate 10. The first semiconductor devices include the first array 20A of line structures and the third array 50A of line structures. Second semiconductor devices can be formed in the second region on the substrate 10. The second semiconductor devices include the second array 20B of line structures and the fourth array 50B of line structures.

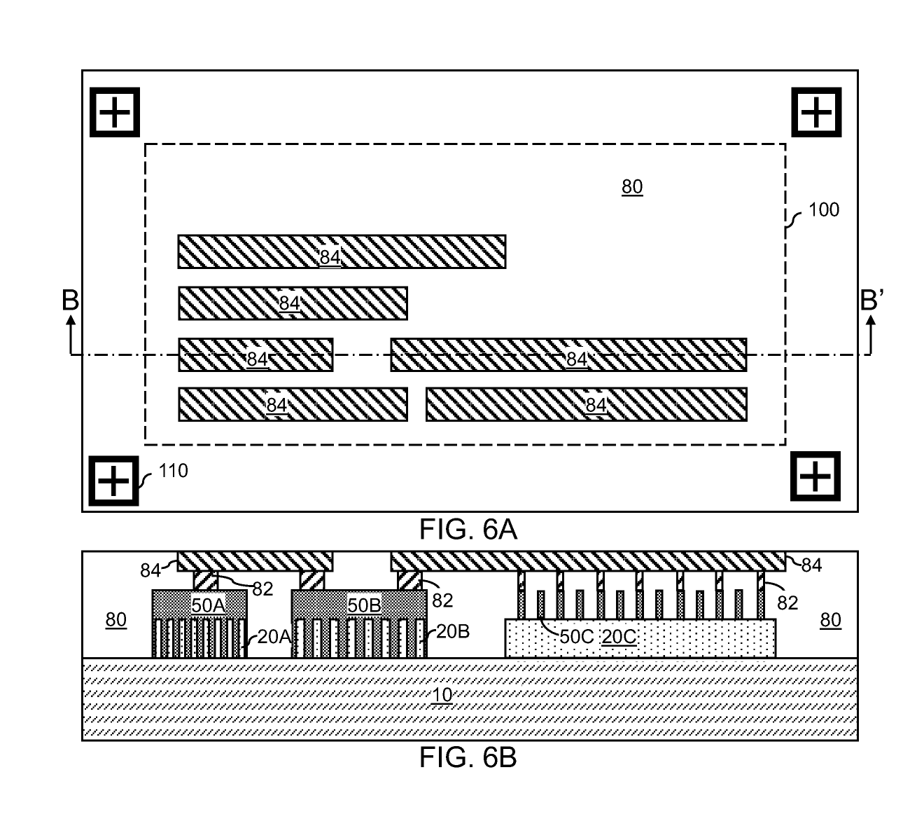

Referring to FIGS. 6A and 6B, at least one interconnect-level dielectric material layer 80 can be deposited over the various arrays (20A, 20B, 20C, 50A, 50B, 50C) of line structures. Various metal interconnect structures can be formed within the at least one interconnect-level dielectric material layer 80. The various metal interconnect structures can include, for example, conductive via structures 82 that contact selected portions of the various arrays (20A, 20B, 20C, 50A, 50B, 50C) of line structures to provide electrical contact to various elements of the semiconductor devices therein or otherwise provide vertical conductive paths, and conductive line structures 84 that contact the conductive via structures 82 and/or otherwise provide horizontal conductive paths.

A semiconductor chip is formed in each semiconductor chip region 100. If a plurality of semiconductor chips is formed on the substrate 10, each semiconductor chip can have an identical set of semiconductor devices. Each semiconductor chip includes first semiconductor devices in the first region and second semiconductor devices in the second region, which are formed on the same substrate 10. The first semiconductor devices and the second semiconductor devices are electrically connected by the metal interconnect structures (82, 84). The metal semiconductor structures (82, 84) overlie, and electrically connect, the first semiconductor devices in the first region, the second semiconductor devices in the second region, and additional semiconductor devices in the third region.

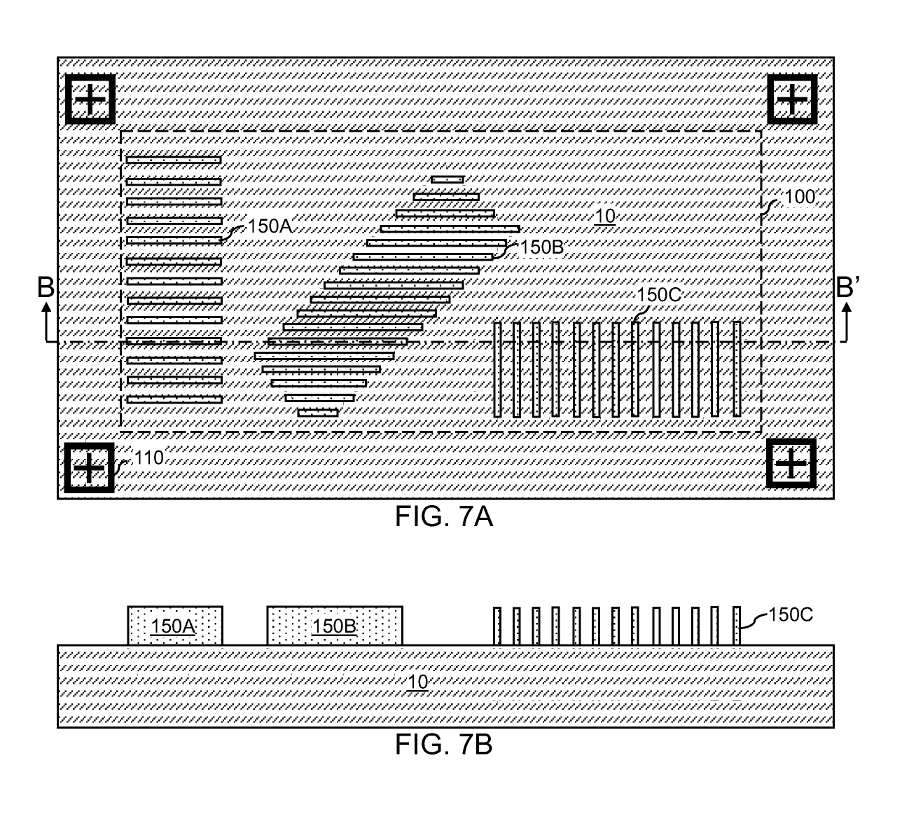

Referring to FIGS. 7A and 7B, the second exemplary patterned structure according to a second embodiment of the present disclosure can be formed by providing a second material layer including a second material on a substrate 10, which can be the same as the substrate 10 of the first embodiment. As noted above, ordinals are employed to distinguish similar elements, and as such, the second material layer refers to a material layer having a different property than another material layer to be subsequently described and referred to as a first material layer.

The second material can be a semiconductor material, a dielectric material, a conductive material, or a combination or a stack thereof. In one embodiment, the second material layer can be a single crystalline semiconductor material layer. The second material layer can be provided as a top semiconductor layer of an SOI substrate, or can be deposited on the substrate 10, for example, by chemical vapor deposition (CVD), physical vapor deposition (PVD), atomic layer deposition (ALD), or a combination thereof.

The second material layer is patterned to form a third array 150A of line structures in a first region, a fourth array 150B of line structures in a second region, and an additional first-level array 150C of line structures in a third region. The third array 150A of line structures and the fourth array 150B of line structures refer to arrays of line structures having a different property than other arrays of line structures to be subsequently described and referred to as a first array or a second array. The patterning of the second material layer can be performed, for example, by a combination of lithographic methods and an anisotropic etch, or by a combination of directed self-assembly method and an anisotropic etch in a manner similar to the processing steps of FIGS. 1A, 1B, 2A, 2B, 3A, and 3B. The anisotropic etch can be selective to the substrate 10. In an illustrative example, the third, fourth, and additional first-level arrays (150A, 150B, 150C) of line structures can be arrays of semiconductor fins.

In one embodiment, conventional lithographic methods can be employed to pattern the second material layer. In this case, the third array 150A of line structures and the fourth array 150B of line structures can extend along a same lengthwise direction, which is herein referred to as a third direction. The third direction refers to a direction that is different from other directions to be subsequently described and referred to as a first direction or a second direction. In one embodiment, the third direction can be along the x-axis of the Cartesian coordinate. If the first-level additional array 150A of line structures is formed, the second-level additional array 150A of line structures may extend along a direction perpendicular to the third direction.

Thus, the third array 150A of line structures is formed in the first region and the fourth array 150B of line structure is formed in the second region. The third array 150A of line structures and the fourth array 150B of line structures include the second material. Each line structure within the third and fourth arrays (150A, 150B) of line structures extends along the third direction.

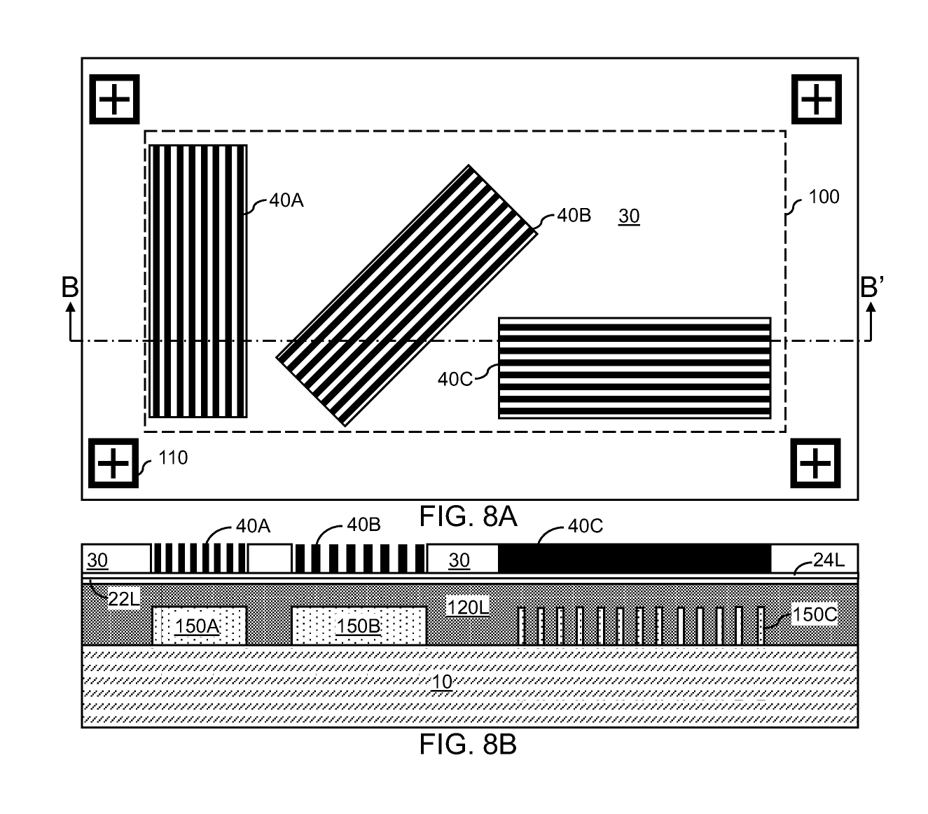

Referring to FIGS. 8A and 8B, a first material layer 120L is deposited over the third array 150A of line structures, the fourth array 150B of line structures, and the first-level additional array 150C of line structures. The first material layer can be a single layer or a stack of multiple layers. Correspondingly, the first material can be a single material or can be a combination of multiple materials corresponding to a stack of multiple layers. In an illustrative example, if the third, fourth, and additional first-level arrays (150A, 150B, 150C) of line structures are arrays of semiconductor fins, the first material layer can include a vertical stack, from bottom to top, of a gate dielectric layer, a gate conductor layer including a conductive material, and an optional gate cap dielectric layer. The first material layer 120L can be deposited, for example, by chemical vapor deposition (CVD), physical vapor deposition (PVD), atomic layer deposition (ALD), or a combination thereof. Optionally, the top surface of the first material layer may be planarized, for example, by chemical mechanical planarization.

A hard mask layer 22L including a dielectric material can be optionally formed on the top surface of the first material layer 120L. The dielectric material of the hard mask layer 22L can be, for example, silicon oxide, silicon nitride, and/or a polymer material layer. The hard mask layer 22L can provide the function of increasing etch budget in case block copolymer material portions do not provide sufficient etch selectivity with respect to the material of the first material layer 120L.

A neutral material layer 24L can be optionally formed on the top surface of the hard mask layer 22L, if the hard mask layer 22L is present, or on the top surface of the first material layer 120L. The neutral material layer 224L includes a material that causes bottom surfaces of block copolymer material portions to align vertically with respect to the substrate 10. If a hard mask layer 22L is provided, the neutral material layer 24L can be a thin polymer material layer having a thickness in a range from 3 nm to 30 nm. If the neutral material layer 24L is formed directly on the top surface of the first material layer 120L, the neutral material layer 24L can have a thickness in a range from 10 nm to 100 nm, and can include a material such as silicon oxide and/or silicon nitride.

Patterned guiding structures for inducing self-assembly of a block copolymer material are subsequently formed over the top surface of the first material layer 120L in the same manner as in the first embodiment. The patterned guiding structures may be a template layer 30 including trenches therein such that sidewalls of the trenches guide a subsequent self-assembly of a block copolymer material, or may be thin patterned layers having edges that guide a subsequent self-assembly of a block copolymer material, or any other temporary structure that may be employed to guide a subsequent self-assembly of a block copolymer material.

The directions of the patterned guiding structures are selected to be different across different regions. In an illustrative example, a first guiding structure having edges extending along a first direction (which is a horizontal direction) can be formed in the first region, a second guiding structure having edges extending along a second direction (which is another horizontal direction) can be formed in a second region, and a third guiding structure having edges extending along a third direction (which is yet another horizontal direction) can be formed in the third region. The same method can be employed to form the patterned guiding structures as in the first embodiment. In one embodiment, the same trenches (31A, 31B, 31C; See FIGS. 1A and 1B) can be formed in the template layer 30 as in the first embodiment.

A block copolymer material is applied over the first material layer 120L, for example, by spin coating. The block copolymer material includes a polymer material (which is herein referred to as a first polymer material) and a second polymer material over the first material layer 20. If the patterned guiding structures are sidewalls of the trenches (31A, 31B, 31C) in a template layer 30, the block copolymer material can be applied within the trenches (31A, 31B, 31C). If the patterned guiding structures are material portions that induce self-alignment of a block copolymer material (such as hydrogen silsesquioxane (HSQ), methyl silsesquioxane (MSQ), a photoresist material, and carbon-based hard mask materials), the block copolymer material can be applied over such material portions. The block copolymer material may be any of the block copolymer material that can be employed in the first embodiment.

The self-assembling block copolymers are first dissolved in a suitable solvent system to form a block copolymer solution, which is applied over the first material layer 120L in the same manner as in the first embodiment. Directed self-assembly of the block copolymer material is subsequently induced. The guiding structures (such as lengthwise sidewalls of the trenches (31A, 31B, 31C) in the template layer 20) guide phase separation and alignment of the block copolymer material during the directed self-assembly. Components of the block copolymer material are aligned to the various guiding structures during the directed self-assembly. The same processing steps can be employed to induce the alignment of the self-assembling block copolymers as in the first embodiment.

First lamellae 40A including the first polymer material, i.e., the first polymeric block component, are formed within the first trench 31A (See FIG. 1A) in the first region, second lamellae 40B including the first polymer material are formed within the second trench 31B (See FIG. 1A) in the second region, and additional lamellae 40C including the first polymer material are formed within the additional trench 31C (See FIG. 1A) in the third region. Thus, the first lamellae 40A, the second lamellae 40B, and the additional lamellae 40C are portions of the block copolymer material that include the first polymer material. First complementary lamellae (not shown) including the second polymer material, i.e., the second polymeric block component, fills the spaces within the first trench 31A that are not filled by the first lamellae 40A. Second complementary lamellae (not shown) including the second polymer material fills the spaces within the second trench 31B that are not filled by the second lamellae 40B. Additional complementary lamellae (not shown) including the second polymer material fills the spaces within the third trench 31C that are not filled by the additional lamellae 40C.

The geometrical features of the guiding structures controls the orientations of the various lamellae (40A, 40B, 40C) including the first polymeric material and the various lamellae including the second polymeric material in the same manner as in the first embodiment. As in the first embodiment, at least a subset of the lamellae (40A, 40B, 40C) including the first polymer material and not contacting lengthwise sidewalls of the trenches (31A, 31B, 31C) can have a same width, which can be in a range from 2 nm to 80 nm. At least a subset of the complementary lamellae (not shown) including the second polymer material and not contacting lengthwise sidewalls of the trenches (31A, 31B, 31C) can have a same width, which can be in a range from 2 nm to 80 nm.

The complementary lamellae can be subsequently removed selective to the first, second, and additional lamellae (40A, 40B, 40C), for example, by an anisotropic etch. The template layer 30 may, or may not, be removed during the anisotropic etch.

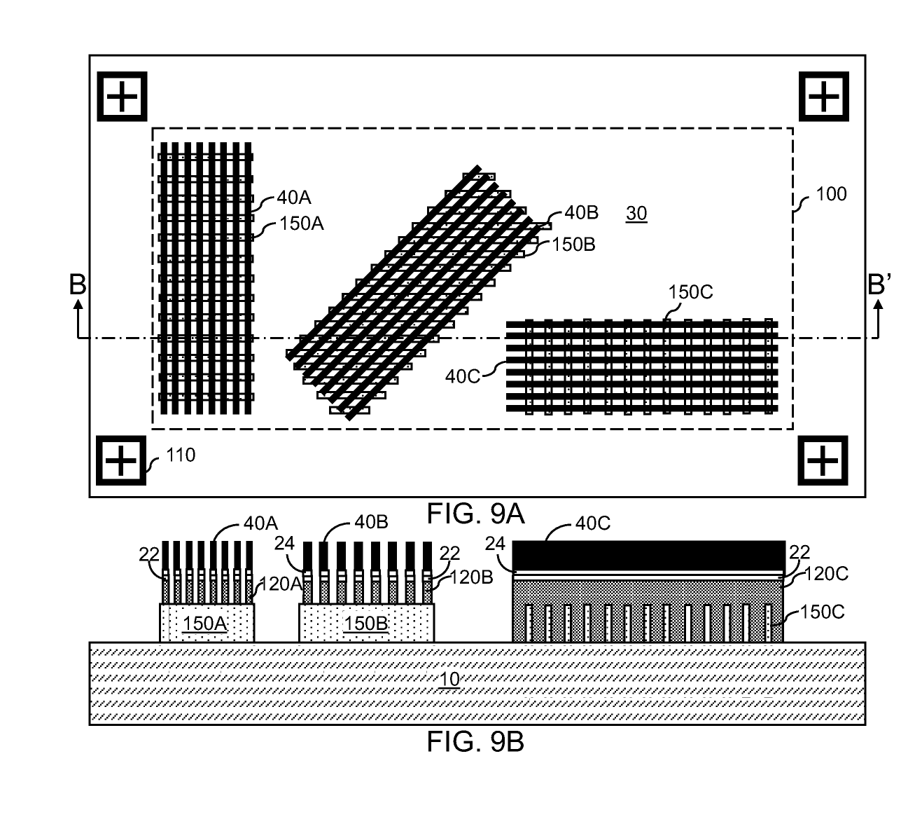

Referring to FIGS. 9A and 9B, a pattern based on the pattern of the lamellae (40A, 40B, 40C) is transferred into the first material layer 120L. In one embodiment, the pattern of the lamellae (40A, 40B, 40C) can be transferred into the first material layer 120L by anisotropically etching any remaining portion of the template layer 30 and the first material layer 120L employing the lamellae (40A, 40B, 40C) as an etch mask.

The remaining portions of the first material layer 120L after the anisotropic etch forms a first array 120A of line structures in the first region, a second array 120B of line structures in the second region, and an additional second-level array 120C of line structures in the third region. The transfer of the pattern of the first lamellae 40A forms the first array 120A of line structures, the transfer of the pattern of the second lamellae 40B forms the second array 120B of line structures, and the transfer of the pattern of the additional lamellae 40C forms the additional second-level array 120C of line structures. The anisotropic etch can be selective to the second material and the material of the substrate 10.

In one embodiment, the second material can be a single crystalline semiconductor material, and the third array 150A of line structures, the fourth array 150B of line structures, and the first-level additional array 150C of line structures can be arrays of single crystalline semiconductor fins.

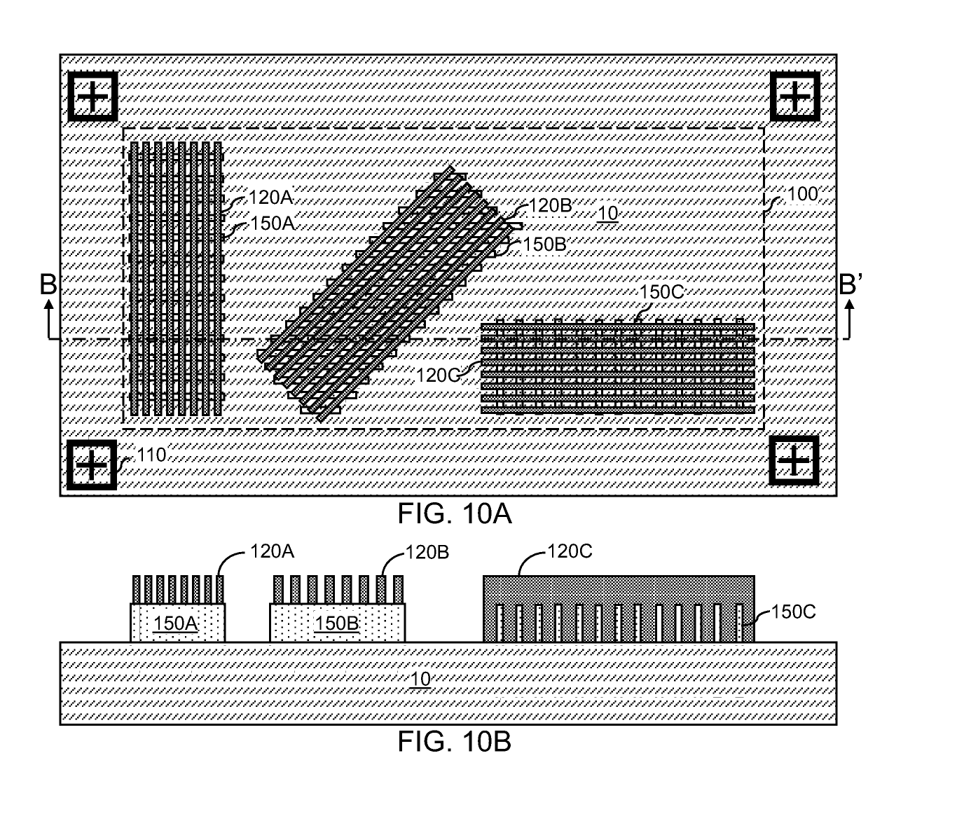

Referring to FIGS. 10A and 10B, the lamellae (40A, 40B, 40C) are removed selective to the first material and the second material, for example, by ashing. In one embodiment, the third array 150A of line structures, the fourth array 150B of line structures, and the additional first-level array 150C of line structures can be arrays of semiconductor fins, and the first array 120A of line structures, the second array 120B of line structures, and the additional second-level array 120C of line structures can be arrays of gate electrode lines. For example, the first array 120A of line structures can be a first array of gate electrode lines, the second array 120B of line structures can be a second array of gate electrode lines, and the additional second-level array 120C of line structures can be a third array of gate electrode lines. Each gate line in the second array 120B of line structures can include a gate dielectric 150B and a gate electrode 54B as illustrated in FIG. 5B. In this case, a source region, a drain region, and a body region can be formed in each of the underlying semiconductor fins. For example, a source region 20S and a drain region 20D can be formed around each gate electrode line and in each semiconductor fin, and a body region 22 can be formed underneath each gate electrode line and in each semiconductor fin as illustrated in FIG. 5B.

In one embodiment, the second exemplary patterned structure can include a first array 120A of line structures in a first region and a second array 120B of line structures in a second region, and a third array 150A of line structures in the first region and a fourth array 150B of line structure in the second region. The first array 120A of line structures and the second array 120B of line structures include the first material, and the third array 150A of line structures and the fourth 150B array of line structures include the second material that is different from the first material. The third array 150A of line structures and the fourth 150B array of line structures underlie the first array 120A of line structures and the second array 120B of line structures, respectively. Each line structure in the first array 120A of line structures extends along a first direction, and each line structure in the second array 120B of line structures extends along a second direction that is not parallel to, and is not perpendicular to, the first direction. The first array 120A of line structures and the second array 120B of line structures can have a same uniform width throughout, which is the width of the first and second lamellae (40A, 40B; See FIG. 8A). The same uniform width can be in a range from 2 nm to 80 nm. Each line structure within the third and fourth arrays (150A, 150B) of line structures extends along a third direction that is different from the first direction and the second direction.

In general, first semiconductor devices can be formed in the first region on the substrate 10. The first semiconductor devices include the first array 120A of line structures and the third array 150A of line structures. Second semiconductor devices can be formed in the second region on the substrate 10. The second semiconductor devices include the second array 120B of line structures and the fourth array 150B of line structures.

Subsequently, at least one interconnect-level dielectric material layer 80 can be deposited over the various arrays (20A, 120B, 120C, 150A, 150B, 150C) of line structures in the same manner as in the first embodiment. See FIGS. 6A and 6B. Various metal interconnect structures can be formed within the at least one interconnect-level dielectric material layer 80 (See FIGS. 6A and 6B). The various metal interconnect structures can include, for example, conductive via structures 82 and conductive line structures 84 in the same manner as in the first embodiment.

A semiconductor chip is formed in each semiconductor chip region 100. If a plurality of semiconductor chips is formed on the substrate 10, each semiconductor chip can have an identical set of semiconductor devices. Each semiconductor chip includes first semiconductor devices in the first region and second semiconductor devices in the second region, which are formed on the same substrate 10. The first semiconductor devices and the second semiconductor devices are electrically connected by the metal interconnect structures (82, 84). The metal semiconductor structures (82, 84) overlie, and electrically connect, the first semiconductor devices in the first region, the second semiconductor devices in the second region, and additional semiconductor devices in the third region.

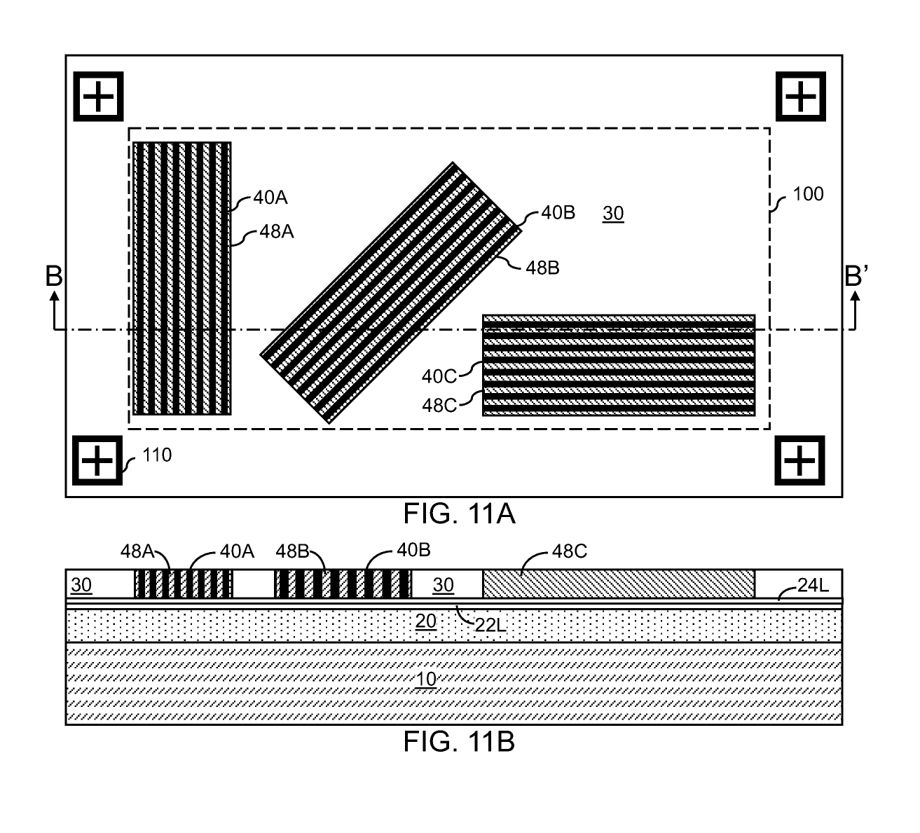

Referring to FIGS. 11A and 11B, a third exemplary patterned structure can be derived from the first exemplary patterned structure of FIGS. 2A and 2B or the second exemplary patterned structure of FIGS. 8A and 8B by filling cavities between lamellae (40A, 40B, 40C) with a planarizing material, which forms fill material portions (48A, 48B, 48C). Specifically, spaces among the first lamellae 40A, spaces among the second lamellae 40B, and spaces among the third lamellae 40C can be filled after removal of the second polymer material selective to the first polymer material without removing the template layer 30. The planarizing material can be a self-planarizing dielectric material such as a spin-on glass (SOG) material. First fill material portions 48A are formed in spaces from which the complementary lamellae within the first trench 31A are removed. (See FIGS. 1A and 1B.) Second fill material portions 48B are formed in spaces from which the complementary lamellae within the second trench 31B are removed. (See FIGS. 1A and 1B.) Third fill material portions 48C are formed in spaces from which the complementary lamellae within the third trench 31C are removed. (See FIGS. 1A and 1B.) The fill material portions (48A, 48B, 48C) have the same width as the complementary lamellae that are replaced by the fill material portions (48A, 48B, 48C).

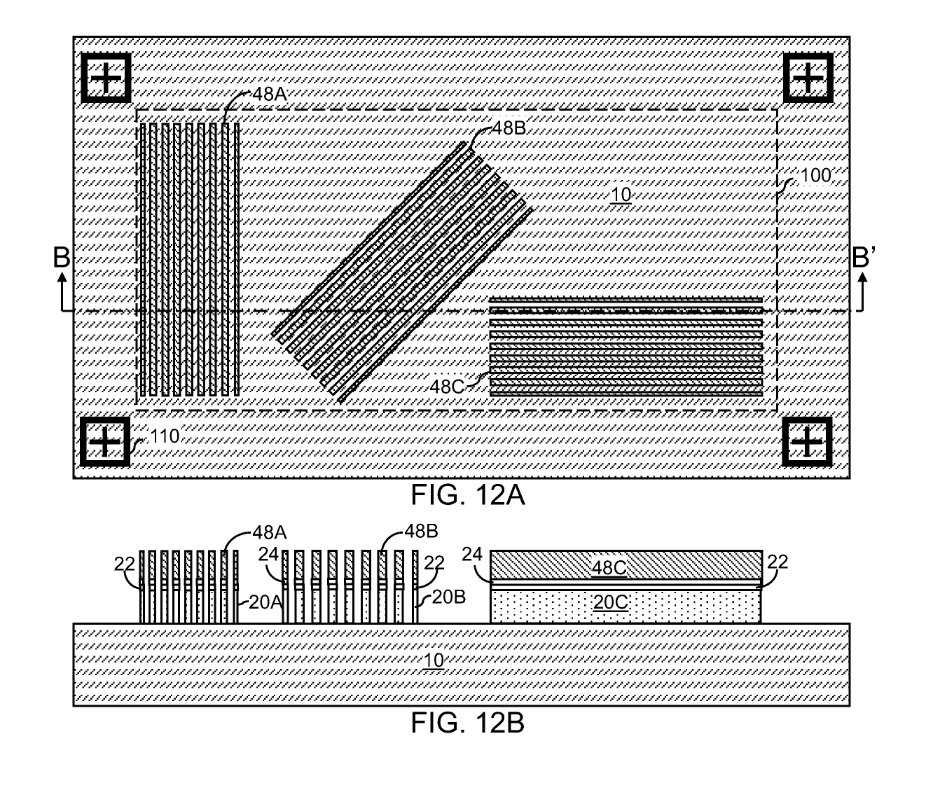

Referring to FIGS. 12A and 12B, the lamellae (40A, 40B, 40C) and the template layer 30 are removed selective to the planarizing material of the fill material portions (48A, 48B, 48C). The pattern of the fill material portions (48A, 48B, 48C) is a pattern based on the pattern of the lamellae (40A, 40B, 40C). Specifically, the pattern of the fill material portions (48A, 48B, 48C) is a complementary pattern of the lamellae (40A, 40B, 40C). Thus, a tone reversal can be performed by the processing steps of FIGS. 11A, 11B, 12A, and 12B.

A pattern based on the pattern of the first lamellae 40A, the pattern of the second lamellae 40B, and the pattern of the third lamellae 40C is transferred into an underlying material layer, which can be the first material layer 20 of the first embodiment or the first material layer 120L of the second embodiment. The pattern of the fill material portions (48A, 48B, 48C) is a complementary pattern of the pattern defined by a combination the first lamellae 40A, the second lamellae 40B, and the third lamellae 40C. The pattern of the fill material portions (48A, 48B, 48C) is transferred into the underlying material layer by anisotropically etching the underlying material layer employing the planarizing material, i.e., the fill material portions (48A, 48B, 48C) as an etch mask after removing the first lamellae 40A, the second lamellae 40B, the third lamellae 40C, and the template layer 30.

The fill material portions (48A, 48B, 48C) can be removed, and the processing steps of FIGS. 4A, 4B, 5A, 5B, 6A, and 6B may be performed as in the first embodiment, or the processing steps of FIGS. 10A and 10B (and optionally the processing steps of FIGS. 6A and 6B) may be performed as in the second embodiment.

The non-orthogonal angle between the second array of line structures and the fourth array of line structures reduces the effect of overlay variations that are inherently introduced when patterning an overlying structure with respect to an underlying structure. The methods of the present disclosure can be employed to form semiconductor devices that are less sensitive to overlay variations.

While the present disclosure has been described in terms of specific embodiments, it is evident in view of the foregoing description that numerous alternatives, modifications and variations will be apparent to those skilled in the art. Each of the various embodiments of the present disclosure can be implemented alone, or in combination with any other embodiments of the present disclosure unless expressly disclosed otherwise or otherwise impossible as would be known to one of ordinary skill in the art. Accordingly, the present disclosure is intended to encompass all such alternatives, modifications and variations which fall within the scope and spirit of the present disclosure and the following claims.

What is claimed is:

1. A structure comprising:
a first array of line structures in a first region and a second array of line structures in a second region, wherein said first array of line structures and said second array of line structures comprise a first material; and
a third array of line structures in said first region and a fourth array of line structure in said second region, wherein said third array of line structures and said second array of line structures comprise a second material different from said first material and overlie, or underlie, said first array of line structures and said second array of line structures, respectively, wherein each line structure in said first array of line structures extends along a first direction and each line structure in said second array of line structures extends along a second direction that is not parallel to, and is not perpendicular to, said first direction, and said first array of line structures and said second array of line structures have a same uniform width throughout, and wherein each line structure within said third and fourth arrays of line structures extends along a third direction that is different from said first direction and said second direction.

2. The structure of claim 1, wherein said third array of line structures overlies said first array of line structures, and said fourth array of line structures overlies said second array of line structures.

3. The structure of claim 2, wherein said first array of line structures is a first array of semiconductor fins, and said second array of line structures is a second array of semiconductor fins.

4. The structure of claim 3, wherein each semiconductor fin in said first and second arrays of semiconductor fins includes at least one source region, at least one drain region, and at least one body region.

5. The structure of claim 2, wherein each of said third array of line structure and said fourth array of line structure is an array of gate lines containing a vertical stack of a gate dielectric and a gate electrode.

6. The structure of claim 1, wherein said first array of line structures overlies said third array of line structures, and said second array of line structures overlies said fourth array of line structures.

7. The structure of claim 6, wherein said third array of line structures is a first array of semiconductor fins, and said fourth array of line structures is a second array of semiconductor fins.

8. The structure of claim 7, wherein each semiconductor fin in said first and second arrays of semiconductor fins includes at least one source region, at least one drain region, and at least one body region.

9. The structure of claim 6, wherein each of said first array of line structure and said second array of line structure is an array of gate lines containing a vertical stack of a gate dielectric and a gate electrode.

10. The structure of claim 1, further comprising:
first semiconductor devices located in said first region and on said substrate and including said first array of line structures and said third array of line structures;
second semiconductor devices located in said second region and on said substrate and including said second array of line structures and said fourth array of line structures; and
metal interconnect structures overlying, and electrically connecting, said first semiconductor devices and said second semiconductor devices.
